(19) United States
(12) Patent Application Publication
(10) Pub. No.: US 2008/0158839 A1
(43) Pub. Date: Jul. 3, 2008

(54) Printed Wiring Board, Printed Circuit Board, and Method of Inspecting Joint of Printed Circuit Board

(75) Inventor: Noboru Nishida, Ome-shi (JP)

Correspondence Address: BLAKELY SOKOLOFF TAYLOR & ZAFMAN, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 11/923,480

(22) Filed: Oct. 24, 2007

(30) Foreign Application Priority Data
Dec. 27, 2006 (JP) 2006-352643

(51) Int. Cl. H05K 7/10

(52) U.S. Cl. 361/767

(57) ABSTRACT

According to one embodiment, a printed wiring board, on which a circuit component including a pad is to be mounted, is provided with a pad which is to be electrically connected to the pad of the circuit component through a conductive joint member. The pad of the printed wiring board includes a separated portion which is located in a peripheral portion thereof and electrically independent of other portion of the pad of the printed wiring board.

### CROSS-REFERENCE TO RELATED APPLICATIONS

This application is based upon and claims the benefit of priority from Japanese Patent Application No. 2006-352643, filed Dec. 27, 2006, the entire contents of which are incorporated herein by reference.

### BACKGROUND

1. Field

Some embodiments of the invention relates to a printed wiring board on which a circuit component including a pad is to be mounted, a printed circuit board on which a circuit component including a pad is mounted, and a method of inspecting a joint of the printed circuit board.

2. Description of the Related Art

Recently, there are circuit components having a relatively large pad on their bottom surface portions for improving thermal dissipation and enhancing ground connection as measures against electromagnetic waves. Printed wiring boards on which such a circuit component is to be mounted are provided with a pad which is to be electrically connected to the pad of the circuit component, for example, by soldering. In manufacturing process of printed circuit boards, it is necessary to inspect a state of connection between the pad of the circuit component and the pad of the printed wiring board. However, it is difficult to perform inspection from the exterior of the printed circuit board, since the pad is provided on the bottom surface of the circuit component.

Jpn. Pat. Appln. KOKAI Pub. No. 2002-43711 discloses a printed wiring board which enables electrical inspection of joint state of pads. The printed wiring board is provided with electrically independent two lands in a position corresponding to one electrode of a circuit component. By measuring resistance between the two lands, it is possible to perform electrical inspection to check whether solder joint includes a defective unmelt.

Some circuit components require soldering of at least predetermined area of a pad thereof. In connection inspection of pads of such circuit components, it is necessary to check whether a necessary connection area is secured, in addition to presence of electrical connection. The above printed wiring board of prior art is aimed at detection of a defective unmelt in solder joints, and not suitable for checking the area of soldered connection.

Since solder tends to collect by surface tension, if the supply amount of solder is insufficient, there are cases where only a center portion of a pad is soldered. Even in these cases, it is determined in the printed wiring board of prior art that two independent pads (lands) are electrically connected to each other, and it is impossible to check whether a necessary connection area is secured.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the present invention;

FIG. 2 is an exemplary cross-sectional view of a printed circuit board according to the first embodiment;

FIG. 3 is an exemplary plan view of a circuit component according to the first embodiment, as viewed from a bottom side thereof;

FIG. 4 is an exemplary plan view of a printed wiring board according to the first embodiment;

FIG. 5 is an exemplary cross-sectional view of a manufacturing process of the printed circuit board according to the first embodiment;

FIG. 6 is an exemplary cross-sectional view of the printed circuit board according to the first embodiment, illustrating inspection of a joint thereof;

FIG. 7 is an exemplary cross-sectional view of the printed circuit board according to the first embodiment, illustrating inspection of a joint thereof;

FIG. 8 is an exemplary cross-sectional view of the printed circuit board according to the first embodiment, illustrating inspection of a joint thereof;

FIG. 9 is an exemplary cross-sectional view of the printed circuit board according to the first embodiment, illustrating inspection of a joint thereof according to another method;

FIG. 10 is an exemplary cross-sectional view of the printed circuit board according to the first embodiment, illustrating inspection of a joint thereof according to another method;

FIG. 11 is an exemplary plan view of a printed wiring board according to a second embodiment of the present invention;

FIG. 12 is an exemplary plan view of a printed circuit board according to the second embodiment; and

FIG. 13 is an exemplary plan view of a printed wiring board according to a third embodiment of the present invention.

### DETAILED DESCRIPTION

Various embodiments according to the invention will be described hereinafter with reference to the accompanying drawings. In general, according to one embodiment of the invention, a printed wiring board, on which a circuit component including a pad is to be mounted, is provided with a pad which is to be electrically connected to the pad of the circuit component through a conductive joint member. The pad of the printed wiring board includes a separated portion which is located in a peripheral portion thereof and electrically independent of other portion of the pad of the printed wiring board.

According to one embodiment of the invention, a printed circuit board is provided with a circuit component including a pad; and a printed wiring board, on which the circuit component is mounted, the printed wiring board including a pad which is electrically connected to the pad of the circuit component through a conductive joint member. The pad of the printed wiring board includes a separated portion which is located in a peripheral portion thereof and electrically independent of other portion of the pad of the printed wiring board.

According to one embodiment of the invention, a method of inspecting a joint of a printed circuit board, includes preparing a printed wiring board including a pad provided with a separated portion which is located in a peripheral portion thereof and electrically independent of other portion of the pad; electrically connecting a pad of the circuit component to the pad of the printed wiring board through a conductive joint member; and checking a state of electrical connection between the separated portion and the conductive joint member.

Embodiments of the present invention are explained below with reference to drawings in which the present invention is applied to portable computers and printed circuit boards included in portable computers.

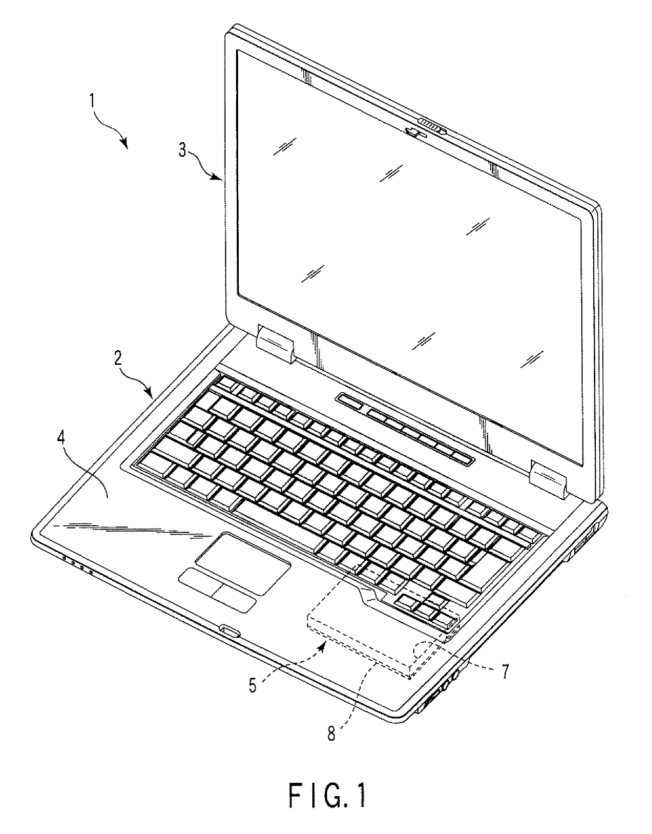

FIG. 1 is an overall view of a portable computer 1. The portable computer 1 is an example of an electronic apparatus to which the present invention is applied. The portable computer 1 comprises a main body 2, and a display unit 3 which is supported by the main body 2 so as to be openable with respect to the main body 2. The main body 2 has a housing 4 having a box shape. The housing 4 contains a hard disk drive (HDD) 5. The HDD 5 has a main body 7 and a printed circuit board 8 serving as a control circuit board which controls the main body 7.

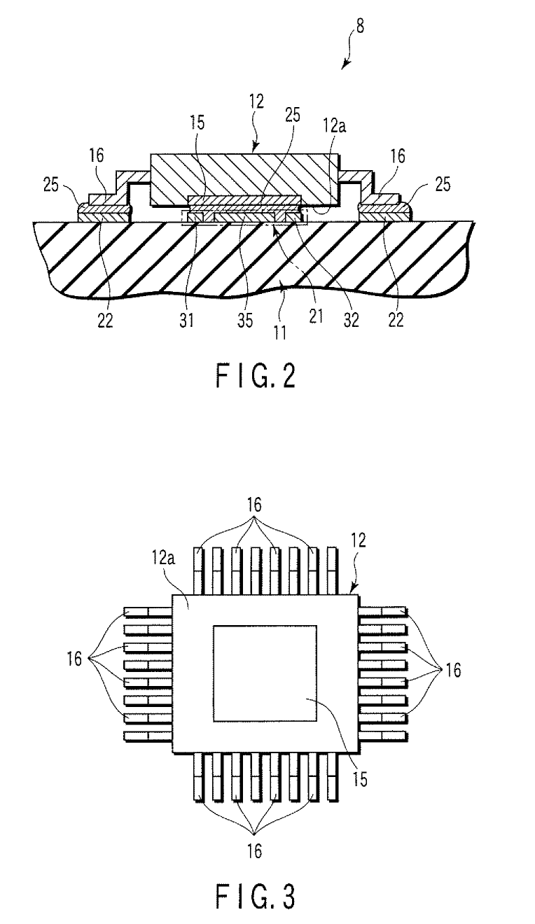

Next, the printed circuit board 8 according to the first embodiment of the present invention is explained with reference to FIGS. 2 to 5.

As illustrated in FIG. 2, the printed circuit board 8 includes a printed wiring board 11 and a circuit component 12 mounted on the printed wiring board 11. An example of the circuit component 12 is a semiconductor package of a quad flat package (QFP) type. To simplify the explanation, a solder resist of the printed wiring board 11 is omitted in FIG. 2. As illustrated in FIG. 2, the circuit component 12 has a pad 15 (hereinafter referred to as “IC pad 15”) on a bottom surface portion 12a thereof.

FIG. 3 illustrates the bottom surface portion 12a of the circuit component 12. The IC pad 15 has a rectangular shape. The IC pad 15 is aimed at improving thermal dissipation and enhancing ground connection as measures against electromagnetic waves, and occupies a relatively large area in the bottom surface portion 12a. The IC pad 15 is used as, for example, a pad for ground connection or a pad for power supply. In the first embodiment, the IC pad 15 for ground connection is explained. An example of the size of the IC pad 15 is about 5 mm×5 mm. A plurality of connecting terminals 16 called leads are provided to each of four sides of the circuit component 12.

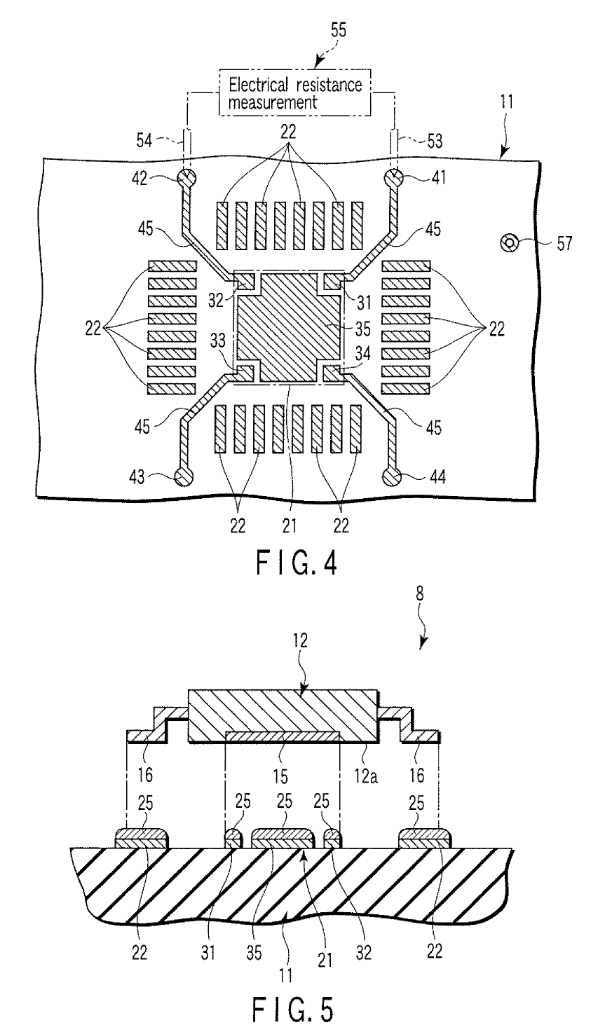

FIG. 4 is a plan view of the printed wiring board 11. In FIG. 4, conductor parts are hatched for explanation thereof. The printed wiring board 11 has a first pad 21 (hereinafter referred to as “first board pad 21”) and a plurality of second pads 22 (hereinafter referred to as “second board pads 22”) in a region where the circuit component 12 is to be mounted. The first board pad 21 is disposed in a position corresponding to the IC pad 15 of the circuit component 12, and has a rectangular shape having almost the same size as that of the IC pad 15.

The second board pads 22 are arranged in positions corresponding to the respective connecting terminals 16 of the circuit component 12. As illustrated in FIG. 2, the first board pad 21 is electrically connected to the IC pad 15 of the circuit component 12 by solder 25. The second board pads 22 are electrically connected to the respective connecting terminals 16 of the circuit component 12 by solder 25. The solder 25 is an example of a conductive joint member of the present invention.

As illustrated in FIG. 4, the first board pad 21 of the first embodiment has a structure in which four corner portions 31, 32, 33 and 34 located in a peripheral portion thereof are separated from a center portion 35. Specifically, the first to fourth corner portions 31, 32, 33 and 34 are spaced from the center portion 35, and electrically independent of the center portion 35. Further, the first to fourth corner portions 31, 32, 33 and 34 are electrically independent of each other. The first to fourth corner portions 31, 32, 33 and 34 are each an example of a separated portion of the pad 21. The center portion 35 is an example of other portion of the pad 21.

Each of the first to fourth corner portions 31, 32, 33 and 34 has, for example, a rectangular shape with a size of about 0.2 mm×0.2 mm to 0.5 mm×0.5 mm. The center portion 35 of the first board pad 21 is electrically connected to a ground located inside the printed wiring board 11.

The printed wiring board 11 is also provided with first to fourth lands 41, 42, 43 and 44. The first land 41 is electrically connected to the first corner portion 31 of the pad 21 through a wire 45. In the same manner, the second to fourth lands 42, 43 and 44 are electrically connected to the second to fourth corner portions 32, 33 and 34, respectively, through respective wires 45.

Next, an example of a manufacturing method of the printed circuit board 8 is explained.

As illustrated in FIG. 5, prepared are the printed wiring board 11 provided with the first and second board pads 21 and 22, and the circuit component 12 provided with the IC pad 15. Next, solder 25 is applied to the first and second board pads 21 and 22 by, for example, screen printing. The solder 25 is printed to, for example, all of center portion 35 and the first to fourth corner portions 31, 32, 33, and 34 of the first board pad 21. The circuit component 12 is mounted on the printed wiring board 11 to which the solder 25 has been applied, and then the solder 25 is molten by reflow processing. The solder 25 bonds the first board pad 21 of the printed wiring board 11 to the IC pad 15 of the circuit component 12, and the second board pads 22 to the connecting terminals 16, and thereby the first board pad 21 is electrically connected to the IC pad 15, and the second board pads 22 are electrically connected to the respective connecting terminals 16.

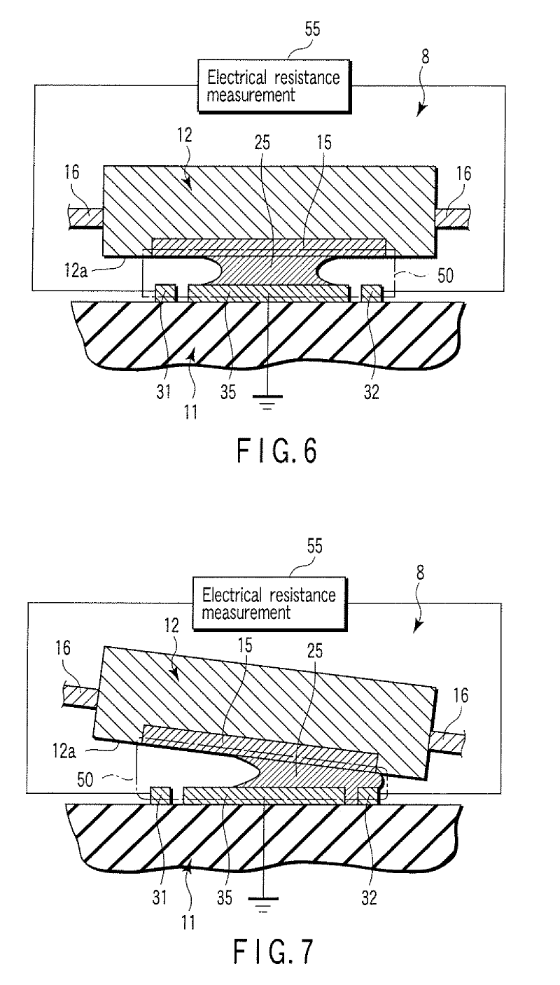

Next, an example of a method of inspecting a state of a joint 50 between the first board pad 21 of the printed wiring board 11 and the IC pad 15 of the circuit component 12 is explained with reference to FIGS. 6 to 8.

The joint 50 is inspected by checking the state of electrical connection between the solder 25 and all or some of the first to fourth corner portions 31, 32, 33 and 34 of the first board pad 21. Various methods can be adopted to check the state of electrical connection. For example, it is possible to detect the state of electrical connection between the solder 25 and the corner portions 31, 32, 33 and 34, by checking conduction (i.e. electrical continuity)between the first to fourth corner portions 31, 32, 33 and 34.

Specifically, a tester 55 having first and second terminals 53 and 54 is prepared as illustrated in FIG. 4, the first terminal 53 is electrically connected to the first land 41 of the printed wiring board 11, and the second terminal 54 is electrically connected to the second land 42. Then, the tester 55 measures electrical resistance between the first land 41 and the second land 42.

If both of the first and second corner portions 31 and 32 of the first board pad 21 are not connected to the solder 25 as illustrated in FIG. 6, or if one of the first and second corner portions 31 and 32 is not connected to the solder 25 as illustrated in FIG. 7, there is no conduction between the first and second corner portions 31 and 32, and there is a large electrical resistance between the first and second lands 41 and 42.

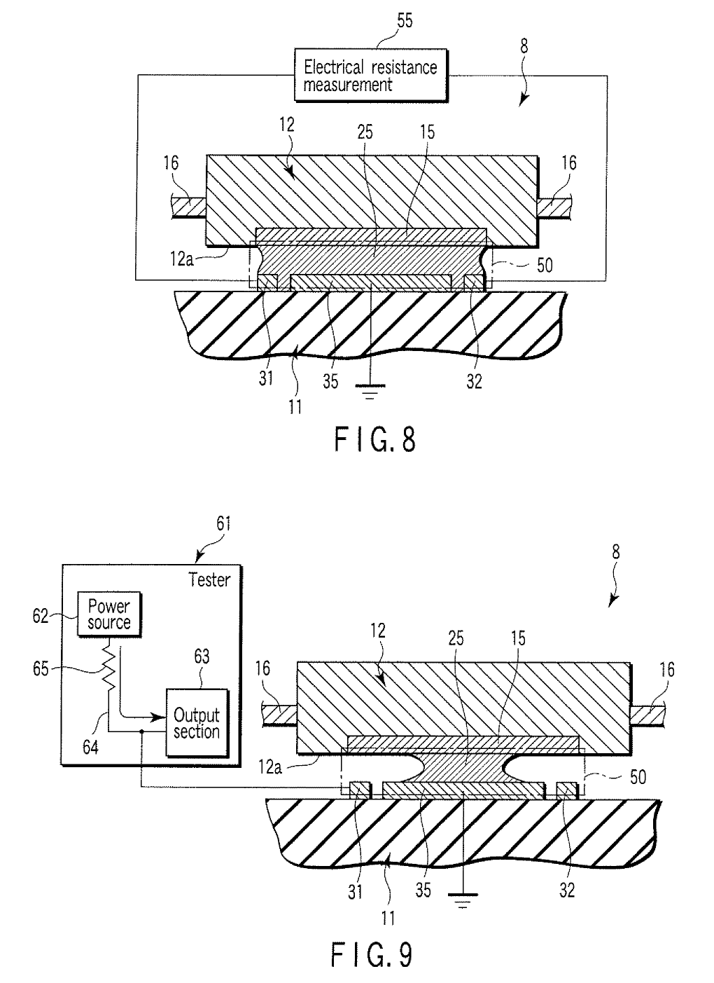

On the other hand, if both of the first and second corner portions 31 and 32 are connected to the solder 25 as illustrated in FIG. 8, there is conduction between the first and second corner portions 31 and 32 through the solder 25 and the IC pad 15, and there is a small electrical resistance between the first and second lands 41 and 42. Specifically, it is possible to check the state of electrical connection between the solder 25 and the first and second corner portions 31 and 32, by checking whether there is conduction between the first and second corner portions 31 and 32. By checking the state of electrical connection between the solder 25 and the first and second corner portions 31 and 32, it is possible to detect whether the first and second corner portions 31 and 32 are connected to the solder 25.

In the same manner, electrical resistance between the third land 43 and the fourth land 44 is measured by using tester 55, and thereby it is detected whether the third and fourth corner portions 33 and 34 are connected to the solder 25, on the basis of the state of electrical connection between the solder 25 and the third and fourth corner portions 33 and 34. The solder connection states of the first to fourth corner portions 31, 32, 33, and 34 are detected as described above. As a result, if it is detected that all the corner portions 31, 32, 33 and 34 are connected to the solder 25, it is regarded that almost the whole areas of the first board pad 21 and the IC pad 15 are connected to the solder 25.

According to the printed wiring board 11, the printed circuit board 8, and the method of inspecting the printed circuit board 8 having the above structures, it is possible to perform more detailed electrical inspection of the state of the joint 50 between the board pad 21 of the printed wiring board 11 and the IC pad 15 of the circuit component 12.

Since the solder 25 tends to collect by its surface tension, if the supply amount of the solder 25 is insufficient, only the central portion of the IC pad 15 is connected to the solder 25 as illustrated in FIG. 6. Although the board pad 21 is electrically connected with the IC pad 15 even in the state of FIG. 6, there are cases where a necessary connection area is not secured if it is required that at least predetermined area (for example, 60% or more) of the IC pad 15 should be soldered.

For example, if the circuit component 12 is mounted in an inclined state with respect to the printed wiring board 11, only a part of the IC pad 15 is connected to the solder 25 as illustrated in FIG. 7. Although the board pad 21 is electrically connected with the IC pad 15 also in the state of FIG. 7, there are cases where a connection area necessary for the circuit component 12 is not secured.

According to the printed wiring board 11 of the first embodiment, it is possible to electrically check whether a connection area necessary for the circuit component 12 is secured, in addition to the electrical connection state between the board pad 21 and the IC pad 15. Specifically, it is possible to detect whether the first and second corner portions 31 and 32 are connected to the solder 25, by checking conduction between the first and second corner portions 31 and 32 of the board pad 21.

In the same manner, it is possible to check whether the third and fourth corner portions 33 and 34 are connected to the solder 25, by checking conduction between the third and fourth corner portions 33 and 34. The solder connection states of the first to fourth corner portions 31, 32, 33, and 34 are detected as described above, and thereby it is checked whether the peripheral portion of the board pad 21 is connected to the solder 25. If it is detected that the peripheral portion of the board pad 21 is connected to the solder 25, it is regarded that almost the whole area of the IC pad 15 is connected to the solder 25.

For example, if all of the first to fourth corner portions 31, 32, 33 and 34 are connected to the solder 25, it is regarded that at least 60% of the area of the IC pad 15 is soldered. Thereby, it is possible to check the extent of soldering of the IC pad 15, that is, whether a connection area necessary for the circuit component 12 is secured or not.

Corners of the board pad 21 having a rectangular shape are one of regions which are not easily connected to the solder 25. Since the separated portions of the pad 21 of the present invention are located in corners of the pad 21, it is possible to more reliably detect insufficient supply of the solder 25. Since at least two portions of the pad 21 are separated from the main part of the pad 21, it is possible to detect a bad connection due to inclination of the circuit component 12.

For example, since the four corner portions 31, 32, 33 and 34 are separated from the center portion 35, it is regarded that almost the whole periphery of the peripheral portion of the board pad 21 is connected to the solder 25, by checking the soldering of the four corner portions 31, 32, 33 and 34. Thereby, the accuracy of inspecting the joint 50 is improved.

The board pad 21, for which solder inspection is performed in the first embodiment, functions as a ground pad. Specifically, by using the peripheral portion of the board pad 21, it is possible to detect the state of the joint 50 while maintaining the function of the board pad 21 which is electrically used.

Even when the IC pad 15 is not electrically connected to the board pad 21, the circuit component 12 is connected to ground through another path. Therefore, if the board pad 21 is a ground pad, it is difficult to check electrical connection between the IC pad 15 and the board pad 21 on the basis of inspection of conduction between the IC pad 15 and the board pad 21. On the other hand, according to the printed wiring board 11 of the first embodiment, it is possible to check whether the board pad 21 is connected to the IC pad 15 by inspecting conduction between the corner portions 31, 32, 33 and 34, even if the board pad 21 is a ground pad.

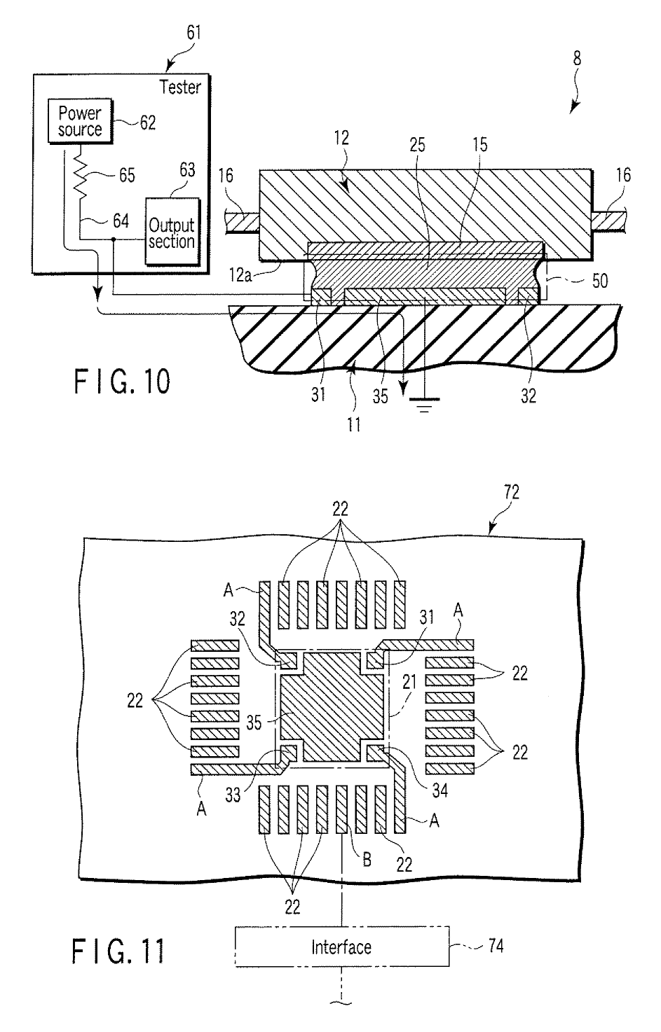

Although conduction between the corner portions 31, 32, 33 and 34 is checked in the first embodiment, the state of electrical connection between the solder 25 and the corner portions 31, 32, 33 and 34 of the board pad 21 may be detected by checking conduction between the center portion 35 and the corner portions 31, 32, 33 and 34 instead. For example, if the first board pad 21 is a ground pad, it may be checked whether there is conduction between another ground pad 57 provided in the printed wiring board 11 and the corner portions 31, 32, 33 and 34 (see FIG. 4), instead of checking conduction between the center portion 35 and the corner portions 31, 32, 33 and 34. [00531 Next, explained is another method of inspecting a state of the joint 50 between the first board pad 21 of the printed wiring board 11 and the IC pad 15 of the circuit component 12, with reference to FIGS. 9 and 10. According to this inspection method, the solder connection states of the corner portions 31, 32, 33 and 34 are detected by checking the potentials of the corner portions 31, 32, 33 and 34.

Specifically, as illustrated in FIG. 9, an example of a tester 61 used for inspection has a power source 62 and an output section 63, and a circuit 64 connecting the power source 62 and the output section 63. The circuit 64 is provided with a pull-up resistor 65. A terminal which is to be connected to, for example, the first land 41 of the printed wiring board 11 is electrically connected to the middle of the circuit 64. By connecting the terminal to the first land 41, the circuit 64 is electrically connected to the first corner portion 31 of the board pad 21.

If the first corner portion 31 is not connected to the solder 25 as illustrated in FIG. 9, the first corner portion 31 is not connected to the ground. Therefore, when a signal current flows from the power source 62, the signal current flows into the output section 63, and a signal in the state of High (H) is input to the output section 63.

On the other hand, if the first corner portion 31 is connected to the solder 25 as illustrated in FIG. 10, there is conduction between the first corner portion 31 and the center portion 35, and the first corner portion 31 is connected to the ground. Therefore, when a signal current flows from the power source 62, the signal current flows into the first corner portion 31, and a signal in the state of Low (L) is input to the output section 63. Specifically, it is checked whether the first corner portion 31 is connected to the solder 25 or not, by checking the state of input to the output section 63. The second to fourth corner portions 32, 33 and 34 are checked in the same manner. The circuit including the power source 62 and the output section 63 may be provided on the printed wiring board 11 instead of the tester 61.

As described above, electrical connection states between the solder 25 and each of the corner portions 31, 32, 33 and 34 can be detected, by checking the potentials of the first to fourth corner portions 31, 32, 33 and 34 and thereby checking conduction between the center portion 35 and each of the corner portions 31, 32, 33 and 34.

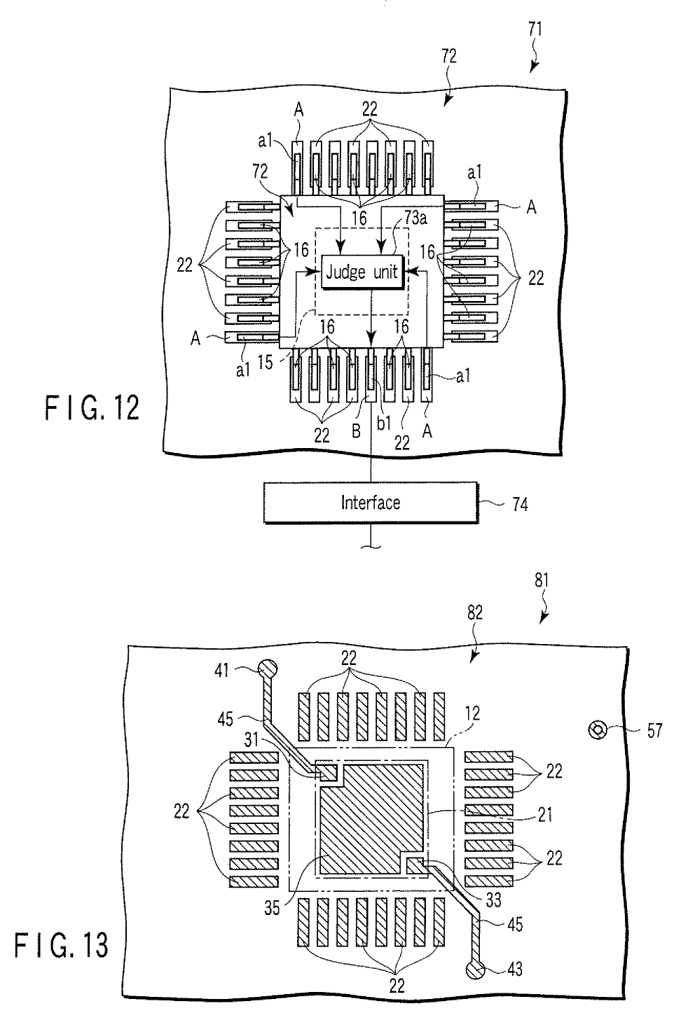

Next, a printed circuit board 71 and a joint inspection method for the printed circuit board 71 according to a second embodiment of the present invention are explained with reference to FIGS. 11 and 12. Constituent elements having the same functions as those of the printed circuit board 8 of the first embodiment are denoted by the same respective reference numerals, and explanation thereof is omitted.

The printed circuit board 71 has a printed wiring board 72, and a circuit component 73 mounted on the printed wiring board 72. The printed wiring board 72 has first and second board pads 21 and 22. In FIG. 11, conductor parts of the printed wiring board 72 are hatched for the explanation thereof. As illustrated in FIG. 11, the second board pads 22 includes pads A and a pad B. For example, four pads A are provided. The pads A are electrically connected to respective near corner portions 31, 32, 33 and 34 of the first board pad 21. The pad B is electrically connected to an interface 74 which is to be connected to an HDD 5.

As illustrated in FIG. 12, the circuit component 73 has an IC pad 15 formed on a bottom surface portion 12a, and connecting terminals 16. The connecting terminals 16 include input terminals al which are electrically connected to the respective pads A of the printed wiring board 72, and an output terminal b1 which is electrically connected to the pad B. The circuit component 73 further has a determination section 73a. The determination section 73a is electrically connected to the input terminals a1 and the input terminal b1. The input terminals a1 are supplied with a pull-up voltage.

Specifically, if some of the corner portions 31, 32, 33 and 34, to which the input terminals a1 are electrically connected, are electrically connected to a ground through a center portion 35, each of the input terminals a1 connected to the ground-connected corner portions inputs an input signal L to the determination section 73. On the other hand, if some of the corner portions 31, 32, 33 and 34 are electrically disconnected from the center portion 35, each of the input terminals a1 electrically connected to the disconnected corner portions inputs an input signal H to the determination section 73a.

The determination section 73a determines whether the corner portions 31, 32, 33 and 34 are connected to solder 25, on the basis of the potentials applied to the respective input terminals a1.

Specifically, if all the input terminals al input an signal L, the determination section 73a determines that all the corner portions 31, 32, 33 and 34 are connected to the solder 25, and that almost the whole areas of the board pad 21 and the IC pad 15 are connected to the solder 25. On the other hand, if any of the input terminals a1 inputs a signal H, the determination section 73a determines that solder connection is insufficient. An example of the determination section 73a is a logic circuit including an AND circuit or an OR circuit.

The determination section 73a outputs a determination result to the outside of the printed circuit board 71 through the output terminal b1 and the interface 74. The information transmitted to the outside of the printed circuit board 71 includes information that all the corner portions 31, 32, 33 and 34 are soldered, or information about disconnected corner portions if non-soldered corner portions are detected.

As described above, a determination mechanism may be provided to the circuit component 73 to check the potentials of the first to fourth corner portions 31, 32, 33 and 34. Thereby, it is possible to check conduction between the center portion 35 and the corner portions 31, 32, 33 and 34, and detect the state of electrical connection between the solder 25 and the corner portions 31, 32, 33 and 34.

According to the printed wiring board 72, the printed circuit board 71, and the inspection method for the printed circuit board 71 having the above structures, it is possible to electrically check the state of joint 50 between the board pad 21 of the printed wiring board 72 and the IC pad 15 of the circuit component 73 in more detail.

According to the printed wiring board 72 of the second embodiment, it is checked whether a connection area necessary for the circuit component 73 is secured, in addition to the electrical connection state between the board pad 21 and the IC pad 15. Specifically, it is checked whether the first to fourth corner portions 31, 32, 33 and 34 are connected to the solder 25, by checking the potentials of the input terminals al which are electrically connected to the first to fourth corner portions 31, 32, 33 and 34.

As described above, the solder connection states of the first to fourth corner portions 31, 32, 33, and 34 are detected as described above, and thereby it is checked whether the peripheral portion of the board pad 21 is connected to the solder 25. If it is detected that the peripheral portion of the board pad 21 is connected to the solder 25, it is regarded that almost the whole area of the IC pad 15 is connected to the solder 25. According to the printed circuit board 71 of the second embodiment, it is unnecessary to perform a conduction test using a tester, and thereby the time necessary for inspection operation is shortened.

Next, a printed circuit board 81 and a joint inspection method for the printed circuit board 81 according to a third embodiment of the present invention are explained with reference to FIG. 13. Constituent elements having the same functions as those of the printed circuit boards 8 and 72 of the first and second embodiments are denoted by the same respective reference numerals, and explanation thereof is omitted.

In FIG. 13, conductor portions are hatched for the explanation thereof. The printed circuit board 81 has a printed wiring board 82, and a circuit component 12. A first board pad 21 of the printed wiring board 82 has a structure in which only first and third corner portions 31 and 33 are separated from a center portion 35. The first and third corner portions 31 and 33 are provided in diagonal corners of the pad 21.

According to the printed wiring board 82, the printed circuit board 81, and the inspection method for the printed circuit board 81 having the above structures, it is possible to electrically check the state of joint 50 between the board pad 21 of the printed wiring board 82 and an IC pad 15 of the circuit component 12 in more detail. Specifically, it is checked whether the first and third corner portions 31 and 33 of the board pad 21 are connected to solder 25, by checking conduction between the first and third corner portions 31 and 33.

The solder connection states of the first and third corner portions 31 and 33 are detected as described above, and thereby it is checked whether the peripheral portion of the board pad 21 is connected to the solder 25. If it is detected that the two corner portions 31 and 33 located in diagonal corners of the board pad 21 are connected to the solder 25, it is regarded that almost the whole area of the IC pad 15 is connected to the solder 25.

Potentials of the corner portions 31 and 33 may be detected by a tester 61 in the same manner as the first embodiment. Pads A electrically connected to the first and third corners 31 and 33, respectively, may be formed in the same manner as the second embodiment, to detect the state of the joint 50 by a circuit component 73 having a determination section 73a.

The present invention is not limited to the printed wiring boards 11, 72 and 82, the printed circuit boards 8, 71 and 81, and the methods of inspecting the joint 50 of the printed circuit boards 8, 71 and 81 according to the first to third embodiments described above. Constituent elements according to the first to third embodiments can be used in combination as desired.

Through holes which are electrically connected to the first to fourth corner portions 31, 32, 33 and 34 can be provided instead of the first to fourth lands 41, 42, 43 and 44, to perform electrical inspection from the back side of the printed wiring board 11, 72 or 82. Further, separated portions of the pad of the present invention are not limited to corner portions of the pad 21, but can be any portions in the peripheral portion of the pad. Providing at least one separate portion in the peripheral portion of the pad 21 will suffice for detecting a bad connection due to short supply of solder 25 or the like.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the Inventions.

What is claimed is:

1. A printed wiring board, on which a circuit component including a pad is to be mounted, comprising:
a pad which is to be electrically connected to the pad of the circuit component through a conductive joint member, and includes a separated portion located in a peripheral portion thereof, the separated portion being electrically independent of other portion of the pad of the printed wiring board.

2. A printed wiring board according to claim 1, wherein
the pad of the printed wiring board has a rectangular shape, and the separated portion is provided in a corner portion of the pad of the printed wiring board.

3. A printed wiring board according to claim 2, wherein
the separated portion is provided in each of two corner portions of the pad of the printed wiring board, which are diagonal to each other.

4. A printed wiring board according to claim 2, wherein
the separated portion is provided in each of four corner portions of the pad of the printed wiring board.

5. A printed wiring board according to claim 1, wherein
the pad of the printed wiring board is a ground.

6. A printed circuit board comprising:
a circuit component including a pad; and
a printed wiring board, on which the circuit component is mounted, the printed wiring board including a pad which is electrically connected to the pad of the circuit component through a conductive joint member,
wherein the pad of the printed wiring board includes a separated portion which is located in a peripheral portion thereof and electrically independent of other portion of the pad of the printed wiring board.

7. A printed circuit board according to claim 6, is wherein
the printed wiring board includes another pad which is electrically connected to the separated portion, and
the circuit component includes an input terminal which is electrically connected to said another pad, a determination section which determines, based on a potential of the input terminal, whether the separated portion is connected to the conductive joint member, and an output terminal which outputs a determination result of the determination section.

8. A method of inspecting a joint of a printed circuit board, comprising:
preparing a printed wiring board including a pad provided with a separated portion which is located in a peripheral portion thereof and electrically independent of other portion of the pad;
electrically connecting a pad of the circuit component to the pad of the printed wiring board through a conductive joint member; and
checking a state of electrical connection between the separated portion and the conductive joint member.

9. A method of inspecting a joint of a printed circuit board according to claim 8, wherein
the state of electrical connection between the separated portion and the conductive joint member is detected by checking conduction between the separated portion and the other portion of the pad of the printed wiring board.

10. A method of inspecting a joint of a printed circuit board according to claim 8, wherein
the pad of the printed wiring board has a rectangular shape, the separated portion is provided in each of two corners of the pad of the printed wiring board, which are diagonal to each other, and
the state of electrical connection between the separated portions and the conductive joint member is detected by checking conduction between the separated portions.
